(19) United States
(12) Patent Application Publication
(10) Pub. No.: US 2025/0046608 A1
(43) Pub. Date: Feb. 6, 2025

(54) METHOD FOR FABRICATING SEMICONDUCTOR DEVICE

(71) Applicant: Samsung Electronics Co., Ltd., Suwon-si (KR)

(72) Inventors: Jin Wook Jung, Suwon-si (KR); Young Duk Suh, Suwon-si (KR); Sun Moon Kim, Suwon-si (KR); Myung-Sik Lee, Suwon-si (KR); Seung Hee Lee, Suwon-si (KR); Do Hyun Jung, Suwon-si (KR)

(21) Appl. No.: 18/441,409

(22) Filed: Feb. 14, 2024

(30) Foreign Application Priority Data
Aug. 3, 2023 (KR) 10-2023-0101712

(51) Int. Cl. H01L 21/02; H01L 21/027

(52) U.S. Cl. CPC H01L 21/02348; H01L 21/0274

(57) ABSTRACT

A method for fabricating a semiconductor device is provided. The method comprises providing a mask which includes first particles, and second particles spaced apart from the first particles, on a surface of the mask, applying a first adhesive over the first particles on the mask, irradiating the first adhesive with light on a first position of the first particles to cure the first adhesive, resulting in a cured first adhesive, forming a first adhesive film from the cured first adhesive in which the first particles are stuck to the first adhesive and removing the first adhesive film on the mask, wherein the first adhesive overlaps a first region of the surface of the mask in which the first particles are disposed, and does not overlap a second region spaced laterally from the first region of the mask.

### CROSS-REFERENCE TO RELATED APPLICATION(S)

This application claims priority from Korean Patent Application No. 10-2023-0101712 filed on Aug. 3, 2023 in the Korean Intellectual Property Office, and all the benefits accruing therefrom under 35 U.S.C. § 119, the contents of which in its entirety are herein incorporated by reference.

### BACKGROUND

The present disclosure relates generally to semiconductor fabrication, and more particularly relates to a method for fabricating a semiconductor device.

In recent years, as a line width of a semiconductor circuit has become progressively smaller, a light source of a shorter wavelength has been required. For example, an extreme ultra-violet (EUV) is often used as an exposure light source. Due to absorption properties of EUV, reflective EUV masks are commonly used in an EUV exposure process. As the level of difficulty of the exposure process becomes greater, small errors of the EUV mask itself may cause significant errors in the formation of circuit patterns on a wafer. Therefore, an EUV mask inspection process for EUV mask defects may be performed. At this time, the defects of the EUV mask may include the presence of contaminants such as fine particles on the EUV mask, errors in the form or size of the pattern formed on the EUV mask, and the like.

### SUMMARY

Aspects of the present disclosure provide a method for fabricating a semiconductor device in which stability is improved.

Aspects of the present disclosure provide a method for fabricating the semiconductor device in which stability is improved.

According to some aspects of the present inventive concept, there is provided a method for fabricating a semiconductor device, the method comprises providing a mask which includes first particles, and second particles spaced apart from the first particles, on a surface, applying a first adhesive which covers the first particles on the mask, irradiating the first adhesive with light on a first position of the first particles to cure the first adhesive, forming a first adhesive film in which the first particles are stuck to the first adhesive and removing the first adhesive film on the mask, wherein the first adhesive overlaps a first region of the surface of the mask in which the first particles are disposed, and does not overlap a second region of the surface of the mask.

According to some aspects of the present inventive concept, there is provided a method for fabricating a semiconductor device, the method comprises providing a mask which includes first particles and second particles spaced apart from the first particles, on a surface applying a first adhesive which covers the first particles on the mask, irradiating the first adhesive with light on the first position of the first particles to cure the first adhesive, forming a first adhesive film in which the first particles are stuck to the first adhesive, removing the first adhesive film from the mask and analyzing the first adhesive film, using a scanning electron microscope, wherein the mask includes a protruding part which protrudes outward from the mask, and a recessed part which is adjacent to the protruding part, and has an upper surface lower than the protruding part on the basis of a lower surface of the mask, wherein the first particle is disposed on the recessed part, and the first adhesive film includes a first portion corresponding to the recessed part, a second portion corresponding to the protruding part, and first particles stuck to the first portion.

According to some aspects of the present inventive concept, there is provided a method for fabricating a semiconductor device, the method comprises providing an EUV photomask which includes first particles and second particles spaced apart from the first particles, on a surface applying a first adhesive which covers the first particles, on the EUV photomask, irradiating the first adhesive with light on a first position of the first particles to cure the first adhesive, forming a first adhesive film in which the first particles are stuck to the first adhesive, removing the first adhesive film from the EUV photomask, applying a second adhesive which covers the second particles, on the EUV photomask, irradiating the second adhesive with light on a second position of the second particles to cure the second adhesive, forming a second adhesive film in which the second particles are stuck to the second adhesive, removing the second adhesive film from the EUV photomask, analyzing the first adhesive film, using a transmission electron microscope or a scanning electron microscope and transferring a pattern onto a semiconductor substrate, using the EUV photomask in which the first particles and the second particles are removed from the surface, wherein the EUV photomask includes a protruding part which protrudes outward from the EUV photomask, and a recessed part which is adjacent to the protruding part, and has an upper surface lower than the protruding part on the basis of a lower surface of the mask, wherein the first adhesive film includes a first portion corresponding to the recessed part and a second portion corresponding to the protruding part, the first particles are disposed on the recessed part, the first adhesive fills the recessed part, the first adhesive film includes the first particles stuck to the first portion, and wherein the first adhesive and the second adhesive are spaced apart from each other.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, wherein like reference numerals (when used) indicate corresponding elements throughout the several views, and in which:

FIG. 1 is a flow chart for explaining an example mask inspection method and a method for fabricating a semiconductor device, according to some embodiments;

FIGS. 2 to 9 are diagrams for conceptually explaining an example mask inspection method, according to one or more embodiments;

FIGS. 10 to 16 are diagrams for explaining an illustrative mask inspection method, according to other embodiments;

FIGS. 17 to 23 are diagrams for explaining an example mask inspection method, according to some other embodiments;

FIGS. 24 to 28 are diagrams for explaining an example mask inspection method, according to some other embodiments; and

FIGS. 29 to 33 are diagrams for explaining an example mask inspection method according to some other embodiments.

### DETAILED DESCRIPTION

Hereinafter, embodiments according to the technical idea of the present disclosure will be described with reference to the accompanying drawings.

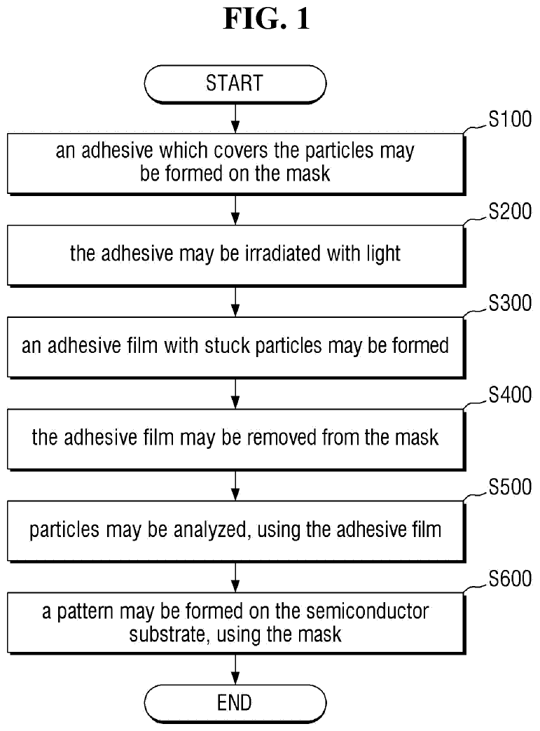

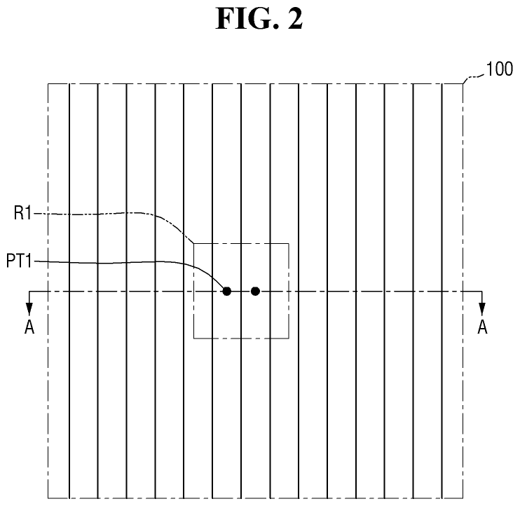

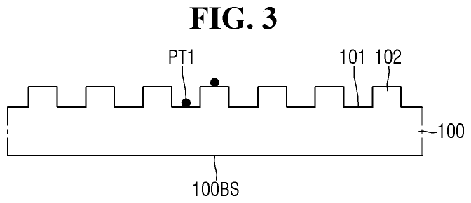

FIG. 1 is a flow chart depicting an example mask inspection method and a method for fabricating a semiconductor device, according to one or more embodiments. FIGS. 2 to 9 are diagrams for explaining an example mask inspection method, according to one or more embodiments. For reference, FIG. 2 is a top plan view of a mask 100, and FIGS. 3 to 6 show cross-sectional views taken along a line A-A of FIG. 2.

Referring to FIGS. 1 to 3, a mask 100 may include first particles PT1. The first particles PT1 may be disposed in a partial region on the mask 100. For example, the first particles PT1 may be disposed in a first region R1 on the mask 100.

The mask 100 may include, for example, an EUV (Extreme Ultra-Violet) photomask. The mask 100 may include a pattern. For example, the mask 100 may include recessed parts 101 and protruding parts 102. The recessed parts 101 and the protruding parts 102 may be alternately disposed on the surface of the mask 100 in a horizontal direction parallel to an upper surface of the mask 100. For example, the pattern of mask 100 may be used when forming the pattern on the semiconductor substrate through an EUV exposure device.

The recessed parts 101 may have an upper surface lower than an upper surface of the protruding parts 102 relative to a lower surface 100BS of the mask. The recessed parts 101 may be disposed between the protruding parts 102. The recessed parts 101 may be recessed from the outside of the mask 100 toward the lower surface 100BS of the mask 100.

The protruding parts 102 may have an upper surface higher than the recessed parts 101 relative to the lower surface 100BS of the mask. The protruding parts 102 may extend outwardly from the upper surface of the mask 100, away from the lower surface 100BS of the mask, in a vertical direction perpendicular to the lower surface 100BS of the mask. The protruding parts 102 may be disposed between the recessed parts 101.

The first particles PT1 may be disposed on one or more of the recessed parts 101 and/or one or more of the protruding parts 102. Although FIG. 3 shows that the first particles PT1 are disposed on one of the recessed parts 101 and one of the protruding parts 102, the embodiment is not limited thereto. For example, the first particles PT1 may be disposed only on the recessed parts 101. As another example, the first particles PT1 may be disposed only on the protruding parts 102.

The diameter of the first particles PT1 may be 50 nanometers (nm) or less, although embodiments are not limited to specific dimensions of the first particles PT1. Even if the recessed parts 101 and the protruding parts 102 are fine in a nano-unit pattern, when the diameter of the first particles PT1 is smaller than the widths of the recessed parts 101 and the protruding parts 102, the first particles PT1 may be disposed on the recessed parts 101 and the protruding parts 102.

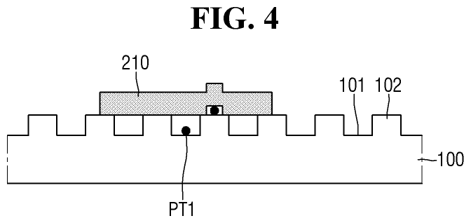

Referring to FIGS. 1 and 4, an adhesive which covers the particles may be formed on the mask (S100). The term “covers” (or “covering,” or like terms), as may be used herein, is intended to broadly refer to an element, structure or layer that is on or over another element, structure or layer, either directly or with one or more other intervening elements, structures or layers therebetween.

A first adhesive 210 may be applied on the mask 100. The first adhesive 210 may be in contact with the surface of the mask 100. For example, the first adhesive 210 may be in contact with the protruding parts 102 of the mask 100. The first adhesive 210 may not be in contact with the recessed parts 101 of the mask 100. However, embodiments are not limited thereto. For example, the first adhesive 210 may be in contact with the recessed parts 101 of the mask 100, or in contact with both the recessed parts 101 and the protruding parts 102 of the mask 100. The term “contact” (or “contacting,” “connect,” “connecting,” or like terms), as may be used herein, is intended to refer to a physical and/or electrical connection between two or more elements, and may include other intervening elements. As used herein, the term “and/or” includes any and all combinations of one or more of the associated listed items.

The first adhesive 210 may cover the plurality of recessed parts 101 and the plurality of protruding parts 102. The first adhesive 210 may overlap the plurality of recessed parts 101 and the plurality of protruding parts 102 in the vertical direction. The term “overlap” (or “overlapping,” or like terms), as used herein, is intended to broadly refer to a first element that intersects with at least a portion of a second element in the vertical direction (i.e., perpendicular to the lower surface 100BS of the mask 100), but does not require that the first and second elements be completely aligned with one another in a horizontal plane (i.e., parallel to the lower surface 100BS of the mask 100).

The first adhesive 210 may overlap the first particles PT1. The first adhesive 210 may cover the first particles PT1. The first adhesive 210 may be in contact with the first particles PT1. For example, the first adhesive 210 may be in contact with the first particles PT1 disposed on the protruding part 102. The first adhesive 210 may not be in contact with the particles PT1 disposed on the recessed part 101. However, the embodiments are not limited thereto. For example, the first adhesive 210 may be in contact with the particles PT1 disposed on the recessed part 101.

The first adhesive 210 may not be applied on the entire region of the mask 100. For example, the first adhesive 210 may be formed only on a partial region in which the first particles PT1 are disposed. For example, the first adhesive 210 may be formed only in the first region (R1 of FIG. 2) of the mask 100. The first adhesive 210 may not be formed in the remaining regions of the mask 100 except for the first region (R1 of FIG. 2).

The first adhesive 210 may be in a solid state. The first adhesive 210 may be disposed, while maintaining the shape applied onto the mask 100 as it is. The first adhesive 210 may not flow on the mask 100.

The first adhesive 210 may include a constituent material different from that of the mask 100. For example, the first adhesive 210 may include a thermoplastic film. The first adhesive 210 may include nano-materials such as nanocube or nanowire. For example, the first adhesive 210 may include metal nanocube having a polyhedral structure. As another example, the first adhesive 210 may include metal nanowire of a facet structure and a structure having a large aspect ratio.

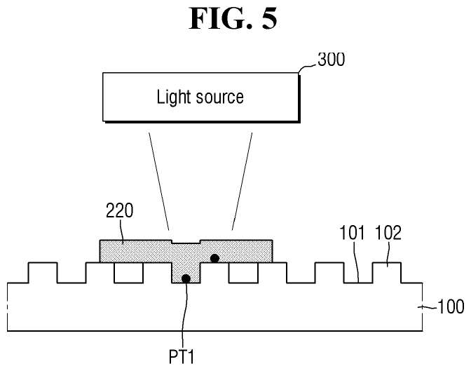

Referring to FIGS. 1 and 5, the adhesive may be irradiated with light (S200).

The first adhesive 210 (FIG. 4) may be irradiated with light on the mask 100, using a light source 300. For example, the light source 300 may provide a laser onto the first adhesive 210. The wavelength of the laser provided onto the first adhesive 210 may be the wavelength at which the absorption rate of the mask 100 is low. For example, the wavelength of the laser provided onto the first adhesive 210 may include 532 nm, 1064 nm, and the like. However, embodiments are not limited thereto. The wavelength of the laser provided onto the first adhesive 210 may vary depending on the embodiment.

The light source 300 may not irradiate the entire first adhesive 210 with light.

Specifically, light may be emitted only onto a partial region of the first adhesive 210 that vertically overlaps the first particles PT1, and light may not be emitted onto the remaining region of the first adhesive 210 that does not overlap the first particles PT1. That is, light may be emitted only onto a local region that covers the first particles PT1 in the entire region of the first adhesive 210. In some embodiments, the light may not be emitted onto the entire first adhesive 210 disposed in the first region (R1 of FIG. 2), and the light may be emitted onto only a partial region of the first adhesive 210 in which the first particles PT1 are disposed, even in the first region (R1 of FIG. 2).

Because the light may be emitted only onto the partial region of the first adhesive 210 in which the first particles PT1 are disposed, the influence of the light on the mask can be minimized. In addition, since the solid first adhesive 210 covers the first particles PT1 and the first adhesive 210 is cured by irradiating the light, it is possible to reduce the likelihood that the first particles PT1 flow in the process in which the first particles PT1 are stuck to form a first adhesive film 220.

The first adhesive film 220 may fill at least one of the recessed parts 101 in which the first particle(s) PT1 reside. The term “fill” (or “filling,” “filled,” or like terms), as may be used herein, is intended to refer broadly to either completely filling a defined space (e.g., the recessed parts 101) or partially filling the defined space; that is, the defined space need not be entirely filled but may, for example, be partially filled or have voids or other spaces throughout. Specifically, the first adhesive film 220 may fill the recessed parts 101 in which the first particles PT1 are disposed. A partial region of the first adhesive 210 irradiated with light may fill the recessed part 101. The first adhesive film 220 may fill the recessed part 101, while the partial region of the first adhesive 210 irradiated with light is cured.

The other region of the first adhesive 210 that is not irradiated with light may not fill the recessed part 101. For example, light may not be emitted onto the first adhesive 210 that overlaps the recessed part 101 in which the first particles PT1 are not disposed. Therefore, the first adhesive 210 that overlaps the recessed part 101 in which the first particles PT1 are not disposed may not fill the recessed part 101.

Next, referring to FIGS. 1 and 5, an adhesive film with stuck particles may be formed (S300).

When the first adhesive 210 is irradiated with light, the first adhesive 210 may be cured to form the adhesive film 220. While the first adhesive 210 is cured, the first particles PT1 may be stuck to the first adhesive 210. The first particles PT1 are stuck to the first adhesive 210, and while the first adhesive 210 is cured, the first adhesive film 220 may be formed.

The first adhesive film 220 that fills the recessed parts 101 may cover the first particles PT1. The first adhesive film 220 may include the first particles PT1 disposed in the recessed parts 101. The first adhesive film 220 may surround (i.e., extend around) the first particles PT1 inside the recessed part 101. The term “surround” (or “surrounds,” or like terms), as may be used herein, is intended to broadly refer to an element, structure or layer that extends around, envelops, encircles, or encloses another element, structure or layer on all sides, although breaks or gaps may also be present. The first adhesive film 220 may be in contact with the first particles PT1 inside the recessed part 101. The first particles PT1 may be stuck inside the first adhesive film 220.

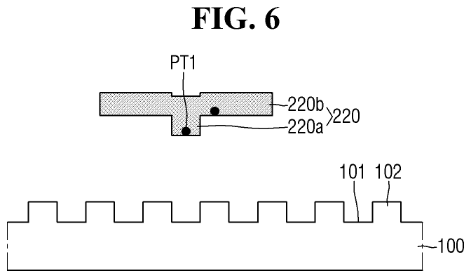

Referring to FIGS. 1 and 6, the adhesive film may be removed from the mask (S400).

The first adhesive film 220 may be removed from the surface of the mask 100. The first adhesive film 220 may be removed from the mask 100 with the first particles PT1 still stuck therein. While the first adhesive film 220 is removed, the first particles PT1 may be removed from the surface of the mask 100.

The first adhesive film 220 may include a first portion 220a and a second portion 220b. The first portion 220a may correspond to the recessed part 101 of the mask 100. The first portion 220a may refer to a portion of the first adhesive film 220 formed by curing the first adhesive 210 in the recessed part 101 of the mask 100. The second portion 220b may correspond to the protruding part 102 of the mask 100. The second portion 220b may refer to a portion of the first adhesive film 220 formed by curing the first adhesive 210 on the protruding parts 102 of the mask 100.

Referring to FIGS. 1, 7, 8 and 9, particles may be analyzed, using the adhesive film (S500).

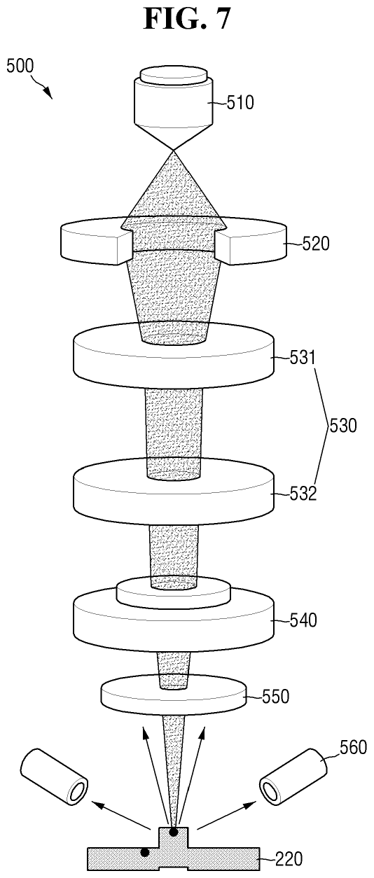

For example, referring to FIG. 7, the first adhesive film 220 may be analyzed, using a scanning electron microscope (SEM) 500. Specifically, the first particles PT1 included in the first adhesive film 220 may be analyzed through the scanning electron microscope.

Components of the first particles PT1 included in the first adhesive film 220 removed from the mask 100 may be analyzed through the scanning electron microscope 500. The first adhesive film 220 may be analyzed through the scanning electron microscope 500 as it is removed from the mask 100 without additional processing.

The scanning electron microscope 500 may include an electron source 510, an electrode 520, a condenser lens 530, an objective lens 540, a first detector 550, and a second detector 560.

The electron source 510 may include, for example, a high energy electron gun. The electron source 510 may generate an electron beam. The electrode 520 may accelerate the electron beam generated by the electron source 510.

The condenser lens 530 may include an upper lens 531 and a lower lens 532. The condenser lens 530 may focus the electron beam generated by the electron source 510 and accelerated by the electrode 520. As the condenser lens 530 focuses the electron beam, the intensity of the electron beam may be varied. The condenser lens 530 may include an aperture. The objective lens 540 may focus the electron beam on the first adhesive film 220.

The first detector 550 may detect back scattering electrons. The first detector 550 may detect electrons reflected and emitted from the surface of the first adhesive film 220. The second detector 560 may detect secondary electrons emitted from the first adhesive film 220 on the basis of the electron beam.

Although not shown, the scanning electron microscope 500 may further include an X-ray analyzer.

On the scanning electron microscope 500, the first adhesive film 220 may be disposed under the objective lens 540.

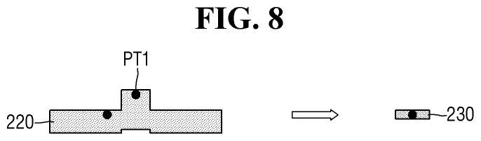

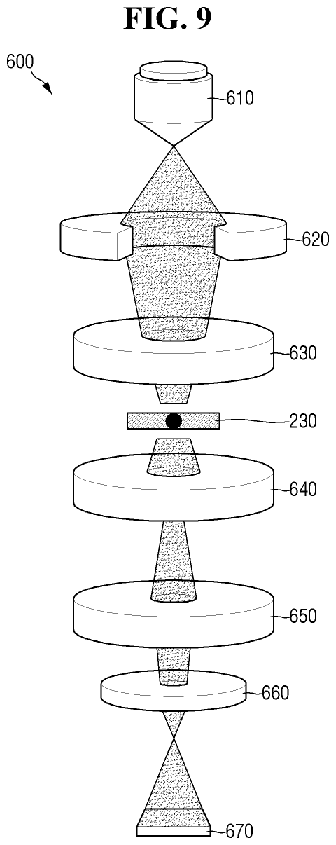

As another example, referring to FIGS. 8 and 9, the first adhesive film 220 may be analyzed, using a transmission electron microscope (TEM) 600. The first adhesive film 220 may be processed to analyze the first adhesive film 220 with the transmission electron microscope 600. A sample 230 may be formed by processing the first adhesive film 220 including the first particles PT1. For example, the sample 230 may be made as a specimen with a uniform thickness of about 300 nm or less, using the first adhesive film 220. The components of the first particles PT1 may be analyzed using sample 230 through the transmission electron microscope 600.

The transmission electron microscope 600 may include an electron source 610, an electrode 620, a condenser lens 630, an objective lens 640, an intermediate lens 650, a projection lens 660 and a screen 670.

The sample 230 may be disposed between the condenser lens 630 and the objective lens 640 on the transmission electron microscope 600.

The electron source 610 may generate an electron beam. The electron source 610 may include, for example, a high energy electron gun. The electrode 620 may accelerate the electron beam generated by the electron source 610.

The condenser lens 630 may focus the electron beam generated by the electron source 610. As the condenser lens 630 focuses the electron beam, the intensity of the electron beam may be varied. The electron beam accelerated by the electrode 620 and focused by the condenser lens 630 may pass through the sample 230.

The objective lens 640 may magnify the electron beam transmitted through the sample 230. The electron beam magnified by the objective lens 640 may form an image on the intermediate lens 650 and the projection lens 660. The electron beam that has passed through the sample 230 may be projected as an image onto the screen 670 through the objective lens 640, the intermediate lens 650 and the projection lens 660.

By analyzing the first particles PT1 attached to the first adhesive film 220, the accuracy of component analysis of the first particles PT1 disposed on the mask 100 may be improved. When the first particles PT1 are directly collected from the mask 100, while the components of the mask 100 are analyzed together, the accuracy of the analysis on the components of the first particles PT1 may be degraded. Also, when the first particles PT1 are directly collected from the mask 100, the mask 100 is likely to be damaged.

On the other hand, when the first particles PT1 are attached to the first adhesive film 220 and collected by removing the first adhesive film 220, the risk of damage to the mask 100 may be reduced. Also, when analyzing the first adhesive film 220 containing a constituent material different from that of the mask 100, the accuracy of the analysis on the components of the first particles PT1 contained in the first adhesive film 220 may be improved.

Next, referring to FIGS. 1 and 6, a pattern may be formed on the semiconductor substrate, using the mask 100 from which the first particles PT1 are removed (S600). For example, the pattern may be formed and transferred onto the semiconductor substrate, using the mask 100 through the EUV exposure device.

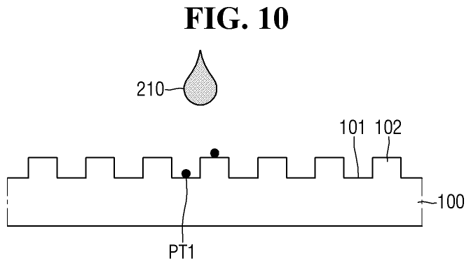

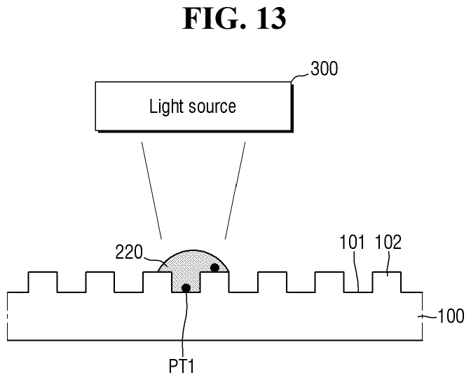

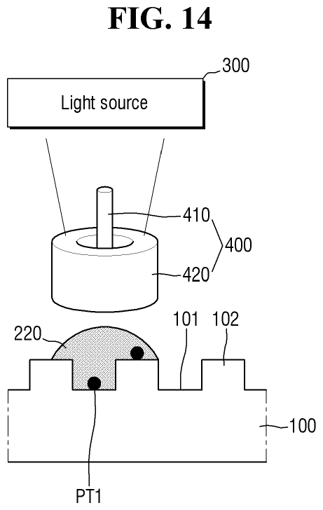

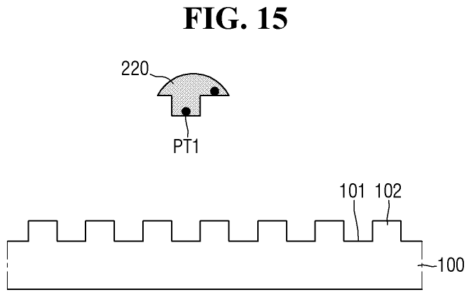

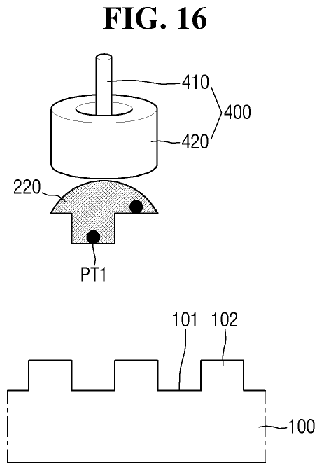

FIGS. 10 to 16 are diagrams for explaining an illustrative mask inspection method according to some embodiments. For convenience of explanation, the description will focus on differences from those described with reference to FIGS. 1 to 9.

Referring to FIGS. 1, 10 and 11, the first adhesive 210 of a solution state may be provided on the mask 100 (S100). For example, the first adhesive 210 may be liquid.

The first adhesive 210 may be applied onto the mask 100 using a particle remover 400. The particle remover 400 may include a nozzle 410 and a transmission structure 420.

The nozzle 410 may be surrounded by the transmission structure 420. The nozzle 410 may extend inside the transmission structure 420. The nozzle 410 may locally apply the first adhesive 210 onto the first particles PT1.

By applying the first adhesive 210 onto the first particles PT1 using the nozzle 410, the flowing possibility of the first particles PT1 may be reduced. For example, when the first adhesive 210 in liquid form is applied to the entire surface of the mask 100, the first particles PT1 contained in the first adhesive 210 may flow on the surface of the mask 100, together with the first adhesive 210. On the other hand, when the first adhesive 210 is applied locally onto the first particles PT1, the possibility of the first particles PT1 flowing over the entire surface of the mask 100 may be reduced.

The transmission structure 420 may surround the nozzle 410. The transmission structure 420 may allow light to transmit. The transmission structure 420 may have a cylindrical shape with an open center. The transmission structure 420 may have a structure that surrounds the nozzle 410, and is movable up and down independently with respect to the nozzle 410.

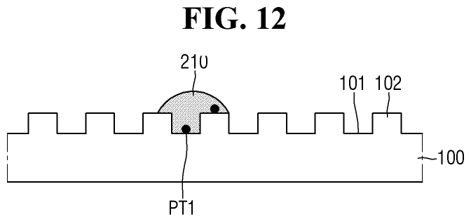

Referring to FIG. 12, the first adhesive 210 may fill the recessed part 101. Since the first adhesive 210 is a solution that has fluidity, it may fill the recessed part 101. The first adhesive 210 may surround the first particles PT1. The first adhesive 210 may cover the first particles PT1 on the protruding part 102, and cover the first particles PT1 inside the recessed part 101.

The first adhesive 210 may not fill other recessed parts 101 directly adjacent to the recessed part 101 in which the first particles PT1 are disposed. The first adhesive 210 applied through the nozzle 410 may be locally formed only in the region in which the first particles PT1 are disposed. Therefore, the first adhesive 210 may not be applied to the other recessed parts 101 spaced apart from the recessed part 101 in which the first particles PT1 are disposed with one protruding part 102 interposed between them.

Referring to FIGS. 1, 13 and 14, a first adhesive film 220 may be formed by irradiating the first adhesive 210 with light, using the light source 300 (S200, S300).

Light emitted from the light source 300 may pass through the transmission structure 420 of the particle remover 400. When transmitting the light, the transmission structure 420 may move closer to the first adhesive 210 than the nozzle 410.

The first adhesive 210 supplied with light may be cured to form the first adhesive film 220. The first adhesive film 220, in solid form, may include the first particles PT1. The first adhesive film 220 may be cured in the shape applied onto the recessed part 101 and the protruding part 102 on the mask 100, as it is. For example, the first adhesive film 220 may include a first portion (220a of FIG. 6) corresponding to the recessed parts 101 of the mask 100 and a second portion (220b of FIG. 6) corresponding to the protruding parts 102 of the mask 100.

Referring to FIGS. 1, 15 and 16, the first adhesive film 220 may be removed from the mask 100 (S400).

The first adhesive film 220 may be removed, using the transmission structure 420 of the particle remover 400. A lower surface of the transmission structure 420 may be in contact with the first adhesive film 220. The first adhesive film 220 may be attached to the lower surface of the transmission structure 420. Therefore, the first adhesive film 220 may be peeled off from the mask 100 by moving the transmission structure 420 to which the first adhesive film 220 is attached. The first particles PT1 stuck to the first adhesive film 220 may also be removed from the mask 100.

Next, the first particles PT1 may be analyzed, using the first adhesive film 220 removed from the mask 100 (S500). For example, the first particles PT1 included in the first adhesive film 220 may be analyzed, through the scanning electron microscope or the transmission electron microscope, as previously described.

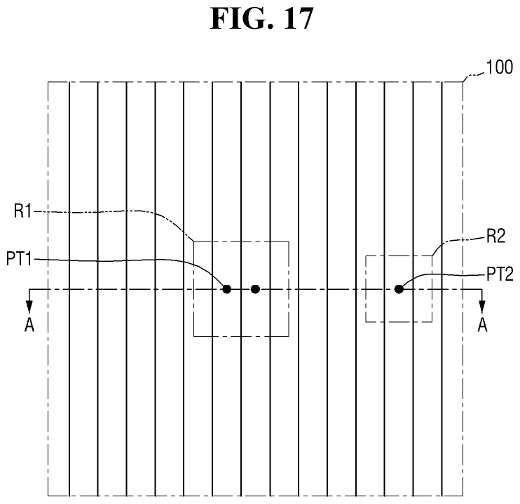

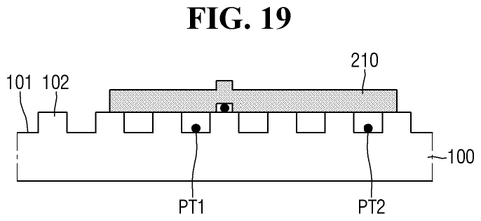

FIGS. 17 to 23 are diagrams for explaining an illustrative mask inspection method, according to some other embodiments. For convenience of explanation, the description will focus on differences from those described with reference to FIGS. 1 to 9.

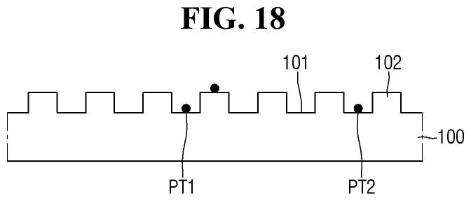

Referring to FIGS. 17 and 18, the mask 100 may include particles in a plurality of regions. The mask 100 may include first particles PT1 and second particles PT2. For example, the first particles PT1 may be disposed in the first region R1 on the mask 100. The second particles PT2 may be disposed in a second region R2 on the mask 100.

The first particles PT1 and the second particles PT2 may be spaced apart from each other in a horizontal plane parallel to an upper surface of the mask 100 (i.e., laterally). The first region R1 and the second region R2 may be laterally spaced apart from each other. Although an example is shown in which two first particles PT1 are disposed in the first region R1 and one second particle PT2 is disposed in the second region R2, the embodiment is not limited thereto. For example, one first particle PT1 may be disposed in the first region R1. As another example, a plurality of second particles PT2 may be disposed in the second region R2.

In the first region R1, the first particles PT1 may be disposed on the recessed part 101 and the protruding part 102. The second particles PT2 may be disposed on the recessed part 101 in the second region R2. However, embodiments are not limited thereto. For example, the second particles PT2 may be disposed on the protruding part 102 in the second region R2.

Referring to FIGS. 1, 17 and 19, the first adhesive 210 may be formed on the mask 100 (S100). The first adhesive 210 may be solid.

The first adhesive 210 may cover both the first region R1 and the second region R2. The first adhesive 210 may be applied over the first region R1 and the second region R2. The first adhesive 210 may overlap the first particles PT1 and the second particles PT2. The first adhesive 210 may cover both the first particles PT1 and the second particles PT2.

The first adhesive 210 may also be applied onto the recessed parts 101 and the protruding parts 102 disposed between the first region R1 and the second region R2. In some embodiments, the solid first adhesive 210 may not be disposed inside the recessed part 101 disposed between the first region R1 and the second region R2.

Referring to FIGS. 1, 20 and 21, the first adhesive 210 may be irradiated with light through the light source 300 (S200).

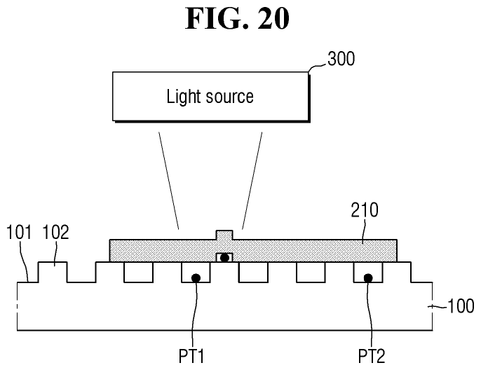

Specifically, referring to FIG. 20, the entire first adhesive 210 may not be irradiated with light, and light may be emitted only to the first region (R1 of FIG. 17) in which the first particles PT1 are disposed. At this time, light may not be emitted to the second region (R2 of FIG. 17) in which the second particles PT2 are disposed. Light may not be emitted to the remaining regions of the first adhesive 210 except for the first region (R1 of FIG. 17) in which the first particles PT1 are disposed.

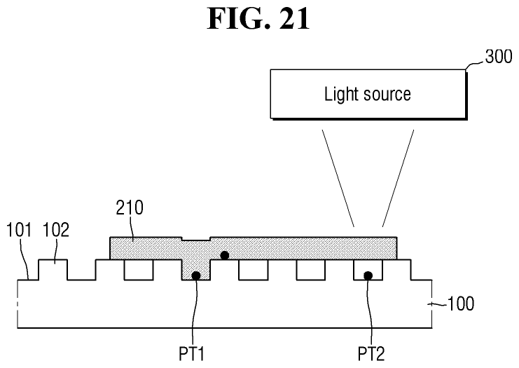

Subsequently, referring to FIG. 21, the entire first adhesive 210 is not irradiated with light, and light may be emitted only to the second region (R2 of FIG. 17) in which the second particles PT2 are disposed. At this time, light may not be emitted to the first region (R1 of FIG. 17) in which the first particles PT1 are disposed. Light may not be emitted to the remaining regions of the first adhesive 210 except for the second region (R2 of FIG. 17) in which the second particles PT2 are disposed.

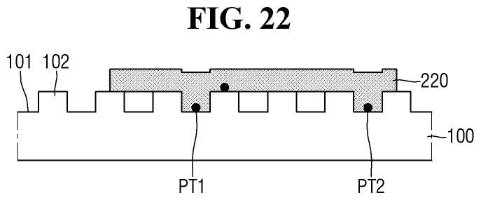

Referring to FIGS. 1 and 22, the first adhesive film 220 to which the first particles PT1 and the second particles PT2 are attached may be formed (S300) as a result of exposure to the light source 300.

The first adhesive film 220 may fill the recessed part 101 in which the first particles PT1 are disposed and the recessed part 101 in which the second particles PT2 are disposed. The first adhesive film 220 may be cured inside the recessed parts 101 in which the first particles PT1 are disposed and the recessed parts 101 in which the second particles PT2 are disposed.

The first adhesive film 220 may overlap the recessed parts 101 in which the first particles PT1 and the second particles PT2 are not disposed, but may not be in contact with the recessed parts 101 in which the first particles PT1 and the second particles PT2 are not disposed. That is, the first adhesive film 220 may not be formed inside the recessed part 101 in which the first particles PT1 and the second particles PT2 are not disposed. This may be due to the fact that the first adhesive film 220 is irradiated with light only in the region in which the first particles PT1 and the second particles PT2 are disposed, and the first adhesive film 220 is not irradiated with light in the region in which the first particles PT1 and the second particles PT2 are not disposed.

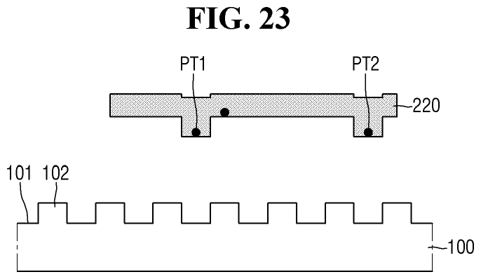

Referring to FIGS. 1 and 23, the first adhesive film 220 may be removed from the mask 100 (S400). The first particles PT1 and the second particles PT2 attached to the first adhesive film 220 may be removed from the surface of the mask 100.

Next, the first particles PT1 and the second particles PT2 may be analyzed, using the first adhesive film 220 (S500). Subsequently, a pattern may be transferred onto the semiconductor substrate, using the mask 100 from which the first particles PT1 and the second particles PT2 are removed (S600).

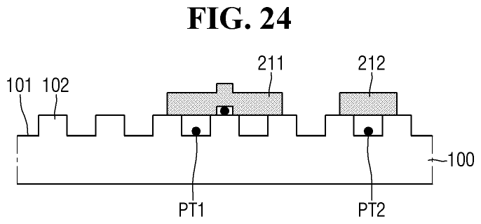

FIGS. 24 to 28 are diagrams for explaining an illustrative mask inspection method according to some other embodiments. For convenience of explanation, the description will focus on points that are different from the descriptions relating to FIGS. 17 to 23.

Referring to FIGS. 1, 17 and 24, a second adhesive 211 and a third adhesive 212 may be formed (S100). The second adhesive 211 and the third adhesive 212 may be solid. The second adhesive 211 and the third adhesive 212 may be spaced apart laterally from each other.

The second adhesive 211 may cover the first region R1. The second adhesive 211 may not cover the second region R2. The second adhesive 211 may overlap the first particles PT1. The second adhesive 211 may cover the first particles PT1. The second adhesive 211 may not overlap the second particles PT2. The second adhesive 211 may not cover the second particles PT2.

The third adhesive 212 may cover the second region R2. The third adhesive 212 may not cover the first region R1. The third adhesive 212 may cover the second particles PT2. The third adhesive 212 may not cover the first particles PT1.

The second adhesive 211 and the third adhesive 212 may not be applied onto the recessed parts 101 and the protruding parts 102 disposed between the first region R1 and the second region R2.

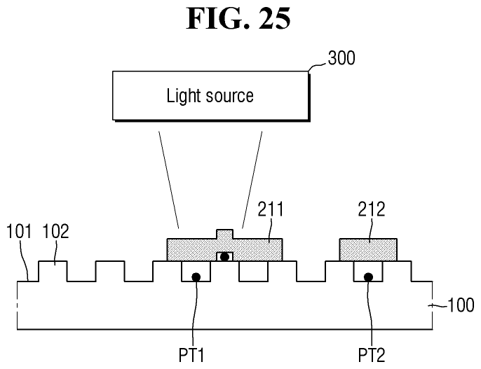

Referring to FIGS. 1 and 25, the second adhesive 211 may be irradiated with light through the light source 300 (S200).

Light may be emitted to the first region (R1 of FIG. 17) in which the first particles PT1 are disposed. Light may be emitted onto the second adhesive 211 disposed in the first region (R1 of FIG. 17). In addition, light may be emitted only onto a local part of the mask 100 in which the first particles PT1 are disposed on the second adhesive 211. Light may not be emitted onto the second adhesive 211 that overlaps the recessed part 101 in which the first particles PT1 are not disposed, in the first region (R1 of FIG. 17).

When the first particles PT1 are irradiated with light, the second region (R2 of FIG. 17) in which the second particles PT2 are disposed may not be irradiated with light. When the first particles PT1 are irradiated with light, light may not be emitted onto the third adhesive 212 disposed in the second region (R2 of FIG. 17). In addition, the light may not be emitted onto the mask 100 in which the second adhesive 211 and the third adhesive 212 are not applied. That is, light may not be emitted onto the exposed surface of the mask 100 that does not overlap the second adhesive 211 and the third adhesive 212.

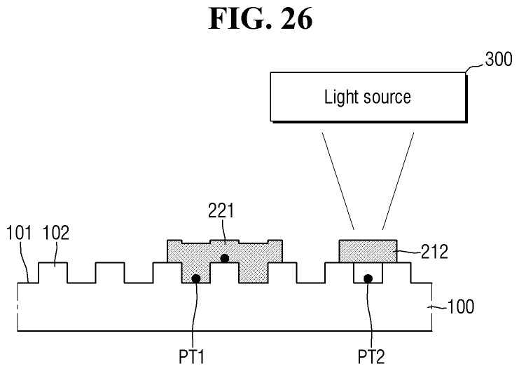

Referring to FIGS. 1 and 26, the third adhesive 212 may be irradiated with light through the light source 300 (S200).

Light may be emitted to the second region (R2 of FIG. 17) in which the second particles PT2 are disposed. Light may be emitted onto the third adhesive 212 disposed in the second region (R2 of FIG. 17). In addition, light may be emitted only onto a local part in which the second particles PT2 are disposed, on the third adhesive 212. Light may not be emitted onto the third adhesive 212 that overlaps the protruding part 102 in which the second particles PT2 are not disposed, in the second region (R2 of FIG. 17).

When the second particles PT2 are irradiated with light, the first region (R1 of FIG. 17) in which the first particles PT1 are disposed may not be irradiated with light. When the second particles PT2 are irradiated with light, light may not be emitted onto the second adhesive 211 disposed in the first region (R1 of FIG. 17). Similarly, light may not be emitted onto the exposed surface of the mask 100 to which the second adhesive 211 and the third adhesive 212 are not be applied.

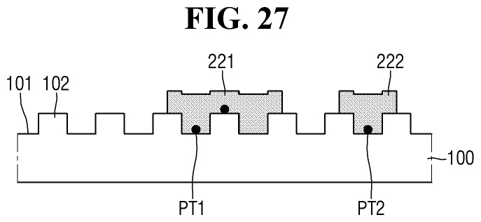

Referring to FIGS. 1 and 27, a second adhesive film 221 to which the first particles PT1 are attached, and a third adhesive film 222 to which the second particles PT2 are attached may be formed (S300) as a result of exposure to the light source 300.

The second adhesive film 221 may fill the recessed parts 101 in which the first particles PT1 are disposed. The second adhesive film 221 may be cured inside the recessed part 101 in which the first particles PT1 are disposed. The second adhesive film 221 may surround the first particles PT1. The first particles PT1 may be attached to the second adhesive film 221.

The third adhesive film 222 may fill the recessed parts 101 in which the second particles PT2 are disposed. The third adhesive film 222 may be cured inside the recessed parts 101 in which the second particles PT2 are disposed. The third adhesive film 222 may surround the second particles PT2. The second particles PT2 may be attached to the third adhesive film 222.

The second adhesive film 221 and the third adhesive film 222 may be spaced apart laterally from each other. The second adhesive film 221 and the third adhesive film 222 may not be connected to each other; that is, the second adhesive film 221 and the third adhesive film 222 may not form a contiguous structure but rather may for separate structures. A surface of the mask 100 may be exposed between the second adhesive film 221 and the third adhesive film 222.

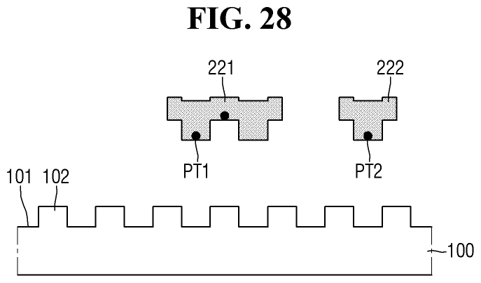

Referring to FIGS. 1 and 28, the second adhesive film 221 and the third adhesive film 222 may be removed from the mask 100 (S400). The first particles PT1 attached to the second adhesive film 221 and the second particles PT2 attached to the third adhesive film 222 may be removed from the surface of the mask 100.

The second adhesive film 221 and the third adhesive film 222 may include a first portion (220a of FIG. 6) corresponding to the recessed part 101 of the mask 100 and a second portion (220b of FIG. 6) corresponding to the protruding part 102, respectively.

Next, referring to FIG. 1, the first particles PT1 may be analyzed, using the second adhesive film 221. The components of the first particles PT1 disposed in the first region (R1 of FIG. 17) may be analyzed, using the second adhesive film 221. The second particles PT2 may be analyzed, using the third adhesive film 222. The components of the second particles PT2 disposed in the second region (R2 of FIG. 17) may be analyzed, using the third adhesive film 222. Subsequently, the pattern may be transferred onto the semiconductor substrate, using the mask 100 from which the first particles PT1 and the second particles PT2 are removed.

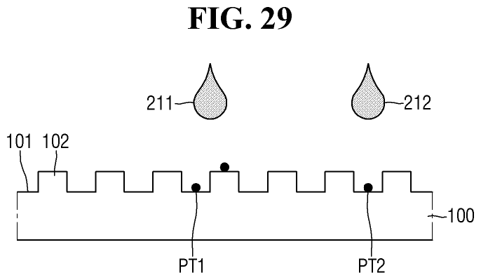

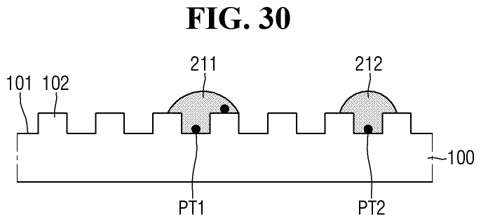

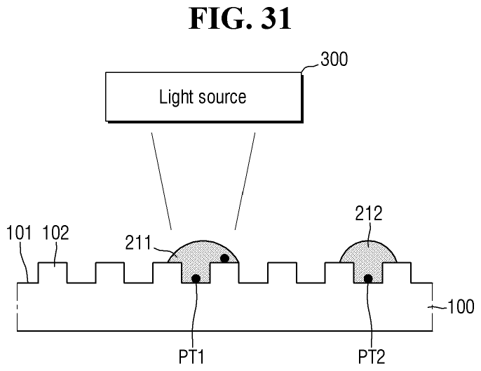

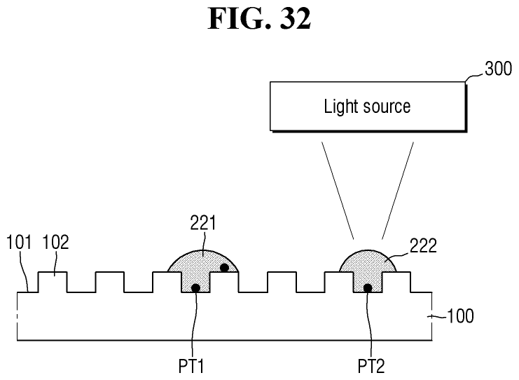

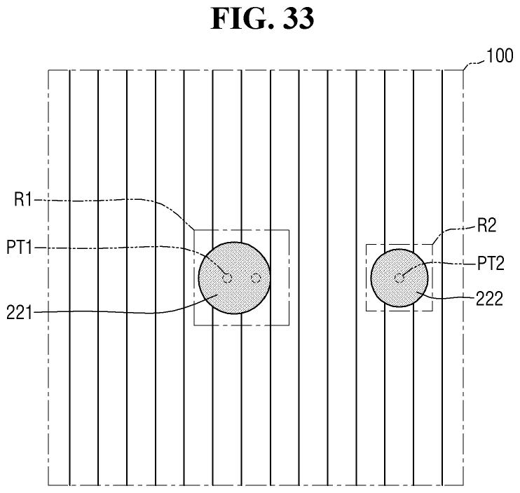

FIGS. 29 to 33 are diagrams for explaining a mask inspection method according to some other embodiments. For convenience of explanation, the explanation will focus on points that are different from those explained using FIGS. 17 to 23.

Referring to FIGS. 1, 17, 29 and 30, the second adhesive 211 and the third adhesive 212 may be applied (S100). The second adhesive 211 and the third adhesive 212 may be solutions. For example, each of the second adhesive 211 and the third adhesive 212 may be in a liquid state. The second adhesive 211 and the third adhesive 212 may be spaced apart laterally from each other.

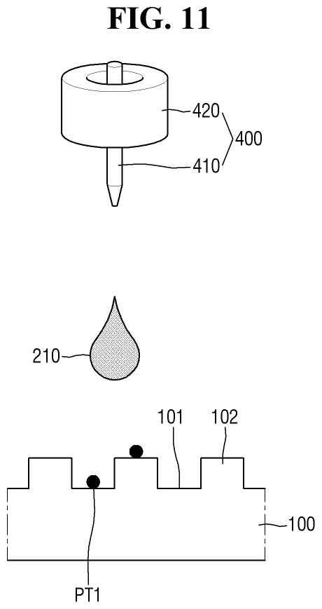

For example, the second adhesive 211 and the third adhesive 212 may be separated and applied onto the first particles PT1 and the second particles PT2, using the particle remover (400 of FIG. 11).

The second adhesive 211 may cover the first region R1. The second adhesive 211 may not cover the second region R2. The second adhesive 211 may overlap the first particles PT1. The second adhesive 211 may cover the first particles PT1. The second adhesive 211 may not overlap the second particles PT2. The second adhesive 211 may not cover the second particles PT2.

The third adhesive 212 may cover the second region R2. The third adhesive 212 may not cover the first region R1. The third adhesive 212 may overlap the second particles PT2. The third adhesive 212 may cover the second particles PT2. The third adhesive 212 may not overlap or cover the first particles PT1.

The second adhesive 211 and the third adhesive 212 may not be applied onto the recessed part 101 and the protruding part 102 disposed between the first region R1 and the second region R2.

The second adhesive 211, being in the liquid state, may fill the recessed parts 101 in which the first particles PT1 are disposed. The third adhesive 212, being in the liquid state, may fill the recessed parts 101 in which the second particles PT2 are disposed.

The second adhesive 211 may not fill the other recessed part 101 that is directly adjacent to the recessed part 101 in which the first particles PT1 are disposed. The third adhesive 212 may fill the other recessed part 101 that is directly adjacent to the recessed part 101 in which the second particles PT2 are disposed.

Referring to FIGS. 1, 31, 32 and 33, the second adhesive 211 may be irradiated with light through the light source 300 (S200). The second adhesive film 221 may be formed by curing the second adhesive 211 on the first particles PT1. The first particles PT1 may be attached to the second adhesive film 221.

The second adhesive film 221 may be disposed only in the first region R1 in which the first particles PT1 are disposed. Although the second adhesive film 221 is shown to cover the two first particles PT1 in the first region R1, the embodiments are not limited thereto. For example, two first particles PT1 may be covered with two different adhesive films in the first region R1.

The third adhesive 212 may be irradiated with light through the light source 300 (S200). The third adhesive film 222 may be formed by curing the third adhesive 212 on the second particles PT2. The second particle PT2 may be attached to the third adhesive film 222.

The third adhesive film 222 may be disposed only in the second region R2 in which the second particles PT2 are disposed. Although the size of the third adhesive film 222 disposed in the second region R2 is shown to be smaller than that of the second adhesive film 221 disposed in the first region R1, the embodiments are not limited thereto. For example, the size of the third adhesive film 222 and the size of the second adhesive film 221 may be identical to each other. As another example, the size of the third adhesive film 222 may be greater than the size of the second adhesive film 221; or the size of the second adhesive film 221 may be greater than the size of the third adhesive film 222.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A method for fabricating a semiconductor device, comprising:
providing a mask which includes first particles, and second particles spaced apart laterally from the first particles, on a surface of the mask;
applying a first adhesive over the first particles on the mask;
irradiating the first adhesive with light on a first position of the first particles to cure the first adhesive, resulting in a cured first adhesive;
forming a first adhesive film from the cured first adhesive in which the first particles are stuck to the first adhesive; and
removing the first adhesive film on the mask,
wherein the first adhesive vertically overlaps a first region of the surface of the mask in which the first particles are disposed, and does not overlap a second region of the mask spaced laterally from the first region of the mask.

2. The method of claim 1,
wherein the first adhesive includes a nanomaterial.

3. The mask of claim 1,
wherein curing of the first adhesive by irradiating the first adhesive with light includes
irradiating with the light only a partial region of the first adhesive that vertically overlaps the first particles, and
not irradiating with the light a region of the first adhesive that does not overlap the first particles.

4. The method of claim 1,
wherein the mask includes an extreme ultra-violet (EUV) photomask.

5. The method of claim 1,
wherein the first adhesive is a solid.

6. The method of claim 5,
wherein the mask further includes third particles spaced laterally apart from the first particles and the second particles and closer to the first particles than the second particles, on the surface of the mask, the method further comprising:
covering the third particles with the first adhesive;
curing the first adhesive further by irradiating the first adhesive with light on a third position of the third particles; and
irradiating the first adhesive with light on the third position by irradiating light separately from irradiating the first adhesive with light on the first position.

7. The method of claim 1,
wherein the first adhesive is a solution, and
applying the first adhesive includes discharging the solution onto the first particles using a nozzle.

8. The method of claim 7,
wherein the mask further includes
a protruding part extending vertically outward from the mask, and
a recessed part which is laterally adjacent to the protruding part, and has an upper surface lower than an upper surface of the protruding part relative to a lower surface of the mask,
wherein the recessed part includes a first recessed part and a second recessed part that are spaced apart laterally from each other with the protruding part interposed therebetween,
the first particle is on the first recessed part, and
discharging the solution includes discharging the solution onto the first recessed part and not discharging the solution onto the second recessed part.

9. The method of claim 7,
wherein irradiating the first position with light includes
irradiating the first position with light transmitted through a transmission structure extending around the nozzle, and
wherein removing the first adhesive film includes
attaching the transmission structure to the adhesive film, and
peeling off the adhesive film from the mask by moving the transmission structure away from the mask.

10. The method of claim 7, further comprising:
discharging a second adhesive over the second particles onto the mask, using the nozzle;
irradiating the second adhesive with light on a second position of the second particles to cure the second adhesive;
forming a second adhesive film from a cured second adhesive in which the second particles are stuck to the second adhesive; and
removing the second adhesive film from the mask,
wherein the first adhesive and the second adhesive are spaced apart laterally from each other.

11. The method of claim 1,
wherein the mask includes
a protruding part extending vertically outward from the mask, and
a recessed part which is adjacent to the protruding part and has an upper surface lower than an upper surface of the protruding part relative to a lower surface of the mask, and
wherein the first adhesive film includes a first portion corresponding to the recessed part, and a second portion corresponding to the protruding part.

12. The method of claim 11,
wherein the first particles are on the recessed part, and
the first adhesive film at least partially fills the recessed part on the mask.

13. The method of claim 1, further comprising:
separating the first adhesive film, using a scanning electron microscope (SEM).

14. The method of claim 1, further comprising:
forming a sample, using the first adhesive film; and
analyzing the sample, using a transmission electron microscope (TEM).

15. A method for fabricating a semiconductor device, comprising:
providing a mask which includes first particles and second particles spaced apart from the first particles, on a surface of the mask;
applying a first adhesive over the first particles on the mask;
irradiating the first adhesive with light on a first position of the first particles to cure the first adhesive, resulting in a cured first adhesive;
forming a first adhesive film from the cured first adhesive in which the first particles are stuck to the first adhesive;
removing the first adhesive film from the mask; and
analyzing the first adhesive film, using a scanning electron microscope,
wherein the mask includes
a protruding part extending vertically outward from the mask, and
a recessed part which is adjacent to the protruding part, and has an upper surface lower than an upper surface of the protruding part relative to a lower surface of the mask,
wherein the first particle is on the recessed part, and
the first adhesive film includes a first portion corresponding to the recessed part, a second portion corresponding to the protruding part, and first particles stuck to the first portion.

16. The method of claim 15,
wherein the first adhesive is a solid,
the recessed part includes a first recessed part and a second recessed part that are spaced apart laterally from each other with the protruding part interposed therebetween,
the first adhesive vertically overlaps the first recessed part and the second recessed part, and
the first adhesive film at least partially fills the first recessed part and does not fill the second recessed part.

17. The method of claim 15,
wherein the first adhesive is a solution, and
applying the first adhesive includes discharging the solution onto the first particles using a nozzle.

18. The method of claim 15,
wherein the first particles have a diameter of about 50 nanometers (nm) or less.

19. A method for fabricating a semiconductor device, the method comprising:
providing an extreme ultra-violet (EUV) photomask which includes first particles and second particles spaced apart laterally from the first particles, on a surface of the EUV photomask;
applying a first adhesive over the first particles, on the EUV photomask;
irradiating the first adhesive with light on a first position of the first particles to cure the first adhesive, resulting in a cured first adhesive;
forming a first adhesive film from the cured first adhesive in which the first particles are stuck to the first adhesive;
removing the first adhesive film from the EUV photomask;
applying a second adhesive over the second particles, on the EUV photomask;
irradiating the second adhesive with light on a second position of the second particles to cure the second adhesive, resulting in a cured second adhesive;
forming a second adhesive film from the cured second adhesive in which the second particles are stuck to the second adhesive;
removing the second adhesive film from the EUV photomask;
analyzing the first adhesive film using a transmission electron microscope or a scanning electron microscope; and
transferring a pattern onto a semiconductor substrate, using the EUV photomask in which the first particles and the second particles are removed from the surface,
wherein the EUV photomask includes
a protruding part extending vertically outward from the EUV photomask, and
a recessed part which is adjacent to the protruding part, and has an upper surface lower than an upper surface of the protruding part relative to a lower surface of the mask,
wherein the first adhesive film includes a first portion corresponding to the recessed part and a second portion corresponding to the protruding part,
the first particles are on the recessed part,
the first adhesive at least partially fills the recessed part,
the first adhesive film includes the first particles stuck to the first portion, and
wherein the first adhesive and the second adhesive are spaced apart laterally from each other.

20. The method of claim 19,
wherein constituent materials of the EUV photomask and constituent materials of the first adhesive are different from each other.
